(19) United States
(12) Patent Application Publication
(10) Pub. No.: US 2016/0266170 A1
(43) Pub. Date: Sep. 15, 2016

(54) LOW OHMIC CURRENT SENSOR CAPABLE OF USING UNTRIMMED RESISTOR TO PROVIDE REQUIRED RESISTANCE

(71) Applicant: Polycon Technology Co., Ltd., Hsinchu City (TW)

(72) Inventor: Yu-Min WANG, Hsinchu City (TW)

(21) Appl. No.: 14/658,105

(22) Filed: Mar. 13, 2015

(51) Int. Cl. G01R 15/14; G01R 19/32; G01R 19/00

(52) U.S. Cl. CPC G01R 15/146; G01R 19/0092; G01R 19/32

(57) ABSTRACT

A low ohmic current sensor capable of using untrimmed resistor to provide required resistance, including: an untrimmed resistor for a current to flow through; an adjustable amplifier unit, having an input port coupled with the untrimmed resistor to receive a current-sense voltage, an output port for providing an output voltage, and a control port for receiving at least one control signal to determine a voltage transfer curve relating the output voltage to the current-sense voltage; and a control unit, having a first port coupled with the control port to provide the at least one control signal, and a second port for accessing at least one control data, wherein the at least one control signal is generated according to the at least one control data.

### BACKGROUND OF THE INVENTION

1. Field of the Invention

The present invention relates to a current sensor, especially to a low ohmic current sensor capable of using untrimmed resistor to provide required resistance.

2. Description of the Related Art

The current sensor, used in many electrical products like motor, battery, power conversion module, etc., can be implemented in different ways such as utilizing a Hall-effect transducer (a contactless current measuring device involving converting a current to a magnetic flux), or a shunt resistor scheme (inserting a resistor in a current path to convert a current thereof to a voltage).

As the Hall-effect transducer is less accurate than the shunt resistor scheme in sensing a current, therefore, the shunt resistor scheme is generally preferred whenever accuracy is particularly required in an application. When the shunt resistor scheme is adopted, to reduce the power consumption, a resistor of small resistance is usually used to convert a current thereof to a voltage. For example, if the shunt resistor scheme is required to provide an output voltage of 1V when the current is equal to 10 Ampere, then, to keep power consumption as low as possible, a trimmed low ohmic resistor of 2 mΩ may be used together with an amplifier having an accurate gain of 50 to attain the output voltage of 1V. That is, both the resistance of the resistor and the gain of the amplifier have to be correct to meet the requirement. However, as the accuracy of a small resistance is difficult to guarantee, a trimming process involving a laser trimming or a mechanical trimming is therefore required, which increases the manufacturing cost substantially.

To solve the foregoing problem, a novel low ohmic current sensor is therefore needed.

### SUMMARY OF THE INVENTION

One objective of the present invention is to disclose a low ohmic current sensor capable of using an untrimmed resistor to provide a required resistance.

Another objective of the present invention is to disclose a low ohmic current sensor capable of using a programmable amplifier circuit to multiply the resistance of an untrimmed resistor with a gain to result in a required resistance.

Still another objective of the present invention is to disclose a low ohmic current sensor capable of using a memory to store control data for resulting in a required resistance without the need of trimming a resistor.

To attain the foregoing objectives, a low ohmic current sensor capable of using untrimmed resistor to provide required resistance is proposed, comprising:

an untrimmed resistor having a first end for introducing in a current and a second end for outputting said current;

an adjustable amplifier unit, having an input port coupled with said first end and said second end to receive a current-sense voltage, an output port for providing an output voltage, and a control port for receiving at least one control signal to determine a voltage transfer curve relating said output voltage to said current-sense voltage;

a control unit, having a first port coupled with said control port to provide said at least one control signal, and a second port for accessing at least one control data, wherein said at least one control signal is generated according to said at least one control data; and

a memory unit for storing said at least one control data.

In one embodiment, the control unit further comprises a third port for receiving at least one external control signal to generate the at least one control data.

In one embodiment, the low ohmic current sensor further comprises a protection unit for providing at least one protection signal according to a comparison result of the output voltage with a first alarm value and/or a comparison result of a temperature signal with a second alarm value.

In one embodiment, the low ohmic current sensor further comprises a temperature coefficient compensation unit coupled with the adjustable amplifier unit to minimize a drift of the voltage transfer curve caused by a temperature change.

In one embodiment, the adjustable amplifier unit comprises an amplifier circuit, of which an input offset and a gain are adjustable by the at least one control signal.

In one embodiment, the low ohmic current sensor is implemented by an integrated circuit.

To attain the foregoing objectives, a method for programming the low ohmic current sensor capable of using untrimmed resistor to provide required resistance is proposed, including:

providing a known current to flow through the untrimmed resistor; and

adjusting the at least one control data until the output voltage reaches a value equal to a product of the known current and a required resistance.

To attain the foregoing objectives, another low ohmic current sensor capable of using untrimmed resistor to provide required resistance is proposed, comprising:

an untrimmed resistor having a first end for introducing in a current and a second end for outputting the current;

an adjustable amplifier unit, having an input port coupled with the first end and the second end to receive a current-sense voltage, an output port for providing an output voltage, and a control port for receiving at least one control signal to determine a gain such that the output voltage is generated by multiplying the current-sense voltage with the gain;

a control unit, having a first port coupled with the control port to provide the at least one control signal, a second port for accessing at least one control data, and a third port for receiving at least one external control signal, wherein the at least one control signal is generated according to the at least one control data, and the at least one external control signal is provided by an external calibration device for determining the at least one control data in a way that, with a known current flowing through the untrimmed resistor, the at least one external control signal is varied until a ratio of the output voltage to the known current is equal to a required resistance; and

a memory unit for storing the at least one control data.

In one embodiment, the low ohmic current sensor capable of using untrimmed resistor to provide required resistance further comprises a protection unit for providing at least one protection signal according to a comparison result of the current with an alarm current value and/or a comparison result of a temperature signal with an alarm temperature value.

In one embodiment, the low ohmic current sensor capable of using untrimmed resistor to provide required resistance further comprises a temperature coefficient compensation unit coupled with the adjustable amplifier unit to minimize a drift of the gain caused by a temperature change.

To make it easier for our examiner to understand the objective of the invention, its structure, innovative features, and performance, we use preferred embodiments together with the accompanying drawings for the detailed description of the invention.

### BRIEF DESCRIPTION OF THE DRAWINGS

FIG. 1 illustrates a block diagram of a low ohmic current sensor capable of using untrimmed resistor to provide required resistance according to a preferred embodiment of the present invention.

FIG. 2 illustrates a flow chart of a method for programming the low ohmic current sensor of FIG. 1 according to an embodiment of the present invention.

FIG. 3 illustrates a block diagram of a low ohmic current sensor according to another embodiment of the present invention.

FIG. 4 illustrates a block diagram of a low ohmic current sensor according to still another embodiment of the present invention.

### DETAILED DESCRIPTION OF THE PREFERRED EMBODIMENTS

The present invention will be described in more detail hereinafter with reference to the accompanying drawings that show the preferred embodiments of the invention.

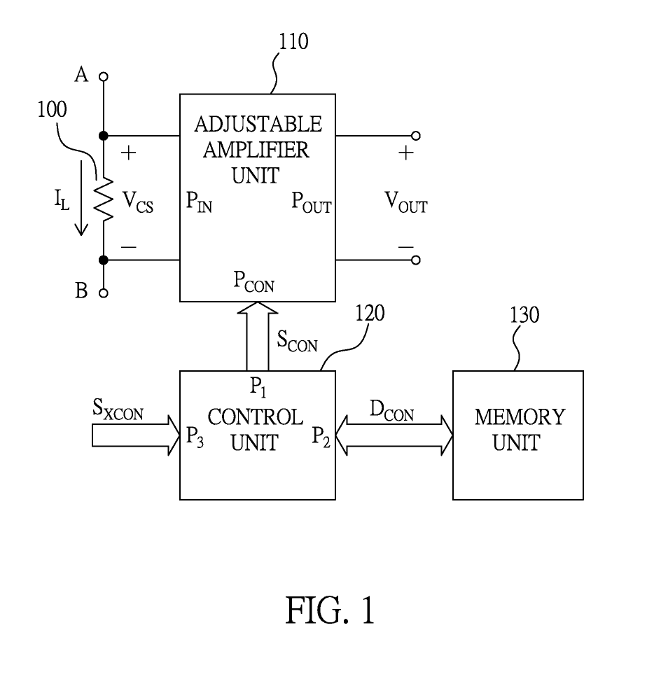

Please refer to FIG. 1, which illustrates a block diagram of a low ohmic current sensor capable of using untrimmed resistor to provide required resistance according to a preferred embodiment of the present invention. As illustrated in FIG. 1, the low ohmic current sensor includes an untrimmed resistor 100, an adjustable amplifier unit 110, a control unit 120, and a memory unit 130.

The untrimmed resistor 100 has a first end (A) for introducing in a current I_{L} and a second end (B) for outputting the current I_{L}.

The adjustable amplifier unit 110 has an input port P_{IN} coupled with the first end (A) and the second end (B) to receive a current-sense voltage V_{CS}, an output port P_{OUT} for providing an output voltage V_{OUT}, and a control port P_{CON} for receiving at least one control signal S_{CON} to determine a voltage transfer curve relating the output voltage V_{OUT} to the current-sense voltage V_{CS} with a gain provided by an amplifier circuit (not shown in the figure). Before adjusting the gain, an input offset of the amplifier circuit can be eliminated beforehand by varying the at least one control signal S_{CON}.

The control unit 120 has a first port P₁ coupled with the control port P_{CON} to provide the at least one control signal S_{CON}; a second port P₂ for accessing at least one control data D_{CON}, wherein the at least one control signal S_{CON} is generated according to the at least one control data D_{CON}; and a third port P₃ for receiving at least one external control signal S_{XCON} to generate the at least one control data D_{CON}.

The memory unit 130, used for storing the at least one control data D_{CON}, is preferably a non-volatile memory.

When programming the low ohmic current sensor of FIG. 1, the at least one external control signal S_{XCON} is provided by an external calibration device (not shown in FIG. 1) for determining the at least one control data D_{CON} in a way that, with a known current flowing through the untrimmed resistor 100, the at least one external control signal S_{XCON} is varied until a ratio of the output voltage V_{OUT} to the known current is equal to a required resistance.

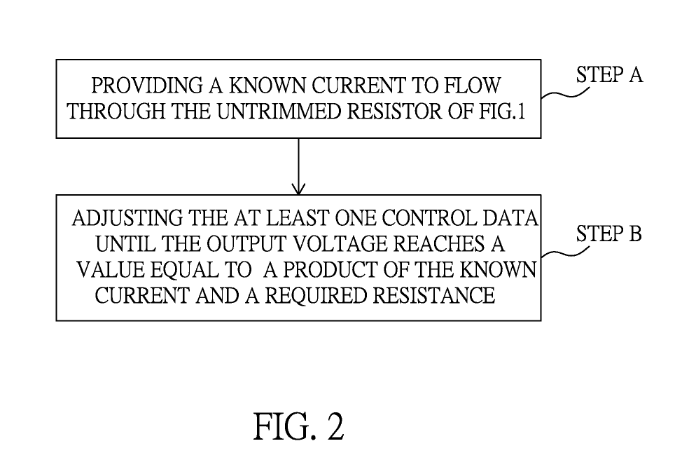

Based on the principle described above, the present invention proposes a method for programming the low ohmic current sensor of FIG. 1. Please refer to FIG. 2, which illustrates a flow chart of a method for programming the low ohmic current sensor of FIG. 1 according to an embodiment of the present invention. As illustrated in FIG. 2, the method includes: providing a known current to flow through the untrimmed resistor of FIG. 1(STEP A); and adjusting the at least one control data until the output voltage reaches a value equal to a product of the known current and a required resistance (STEP B). The known current can be provided by a precision current source.

As an example, if the output voltage is required to be 1V when the known current is 10 Ampere, and the untrimmed resistor 100 has a resistance of 2.2 mΩ, which is higher than an assumed resistance of 2 mΩ by 10%, then, with the gain of the adjustable amplifier unit 110 adjusted to 45.45, the required output voltage of 1V can be easily attained. That is, by simply adjusting the at least one control data until the output voltage V_{OUT} reaches 1V, a low ohmic current sensor of the present invention can be in agreement with the requirement of a current sense application no matter what the resistance of the untrimmed resistor 100 is. That is, for the present invention to meet different applications' need, all we have to do is to set the at least one control data, which is far more convenient and cost effective than the conventional schems' trimming a resistor mechanically or by laser.

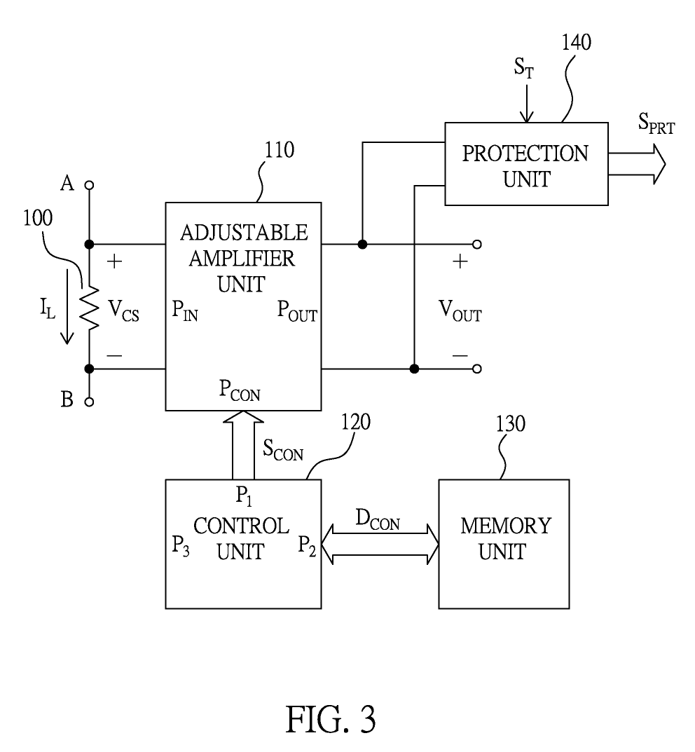

In addition to the output voltage V_{OUT}, a protection function can also be included in the low ohmic current sensor of the present invention. Please refer to FIG. 3, which illustrates a block diagram of a low ohmic current sensor according to another embodiment of the present invention. As illustrated in FIG. 3, the low ohmic current sensor includes an untrimmed resistor 100, an adjustable amplifier unit 110, a control unit 120, a memory unit 130, and a protection unit 140.

The functions of the untrimmed resistor 100, the adjustable amplifier unit 110, the control unit 120, and the memory unit 130 have been specified above, so they will not be readdressed here.

The protection unit 140 is used for providing at least one protection signal S_{PRT} according to a comparison result of the output voltage V_{OUT} with a first alarm value and/or a comparison result of a temperature signal S_{T} with a second alarm value. The first alarm value is set for indicating a maximum permeable current to flow through the untrimmed resistor 100, and the second alarm value is set for indicating a maximum permeable temperature. When the at least one protection signal S_{PRT} is active, it indicates that an over-current situation or an over-temperature situation happens.

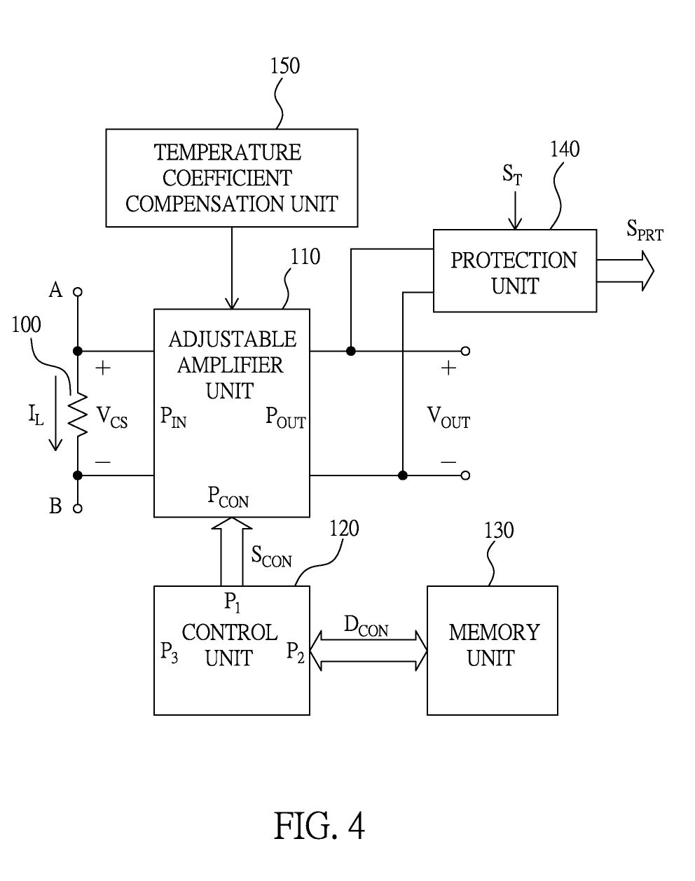

In addition to the protection function, a temperature coefficient compensation function can also be included in the low ohmic current sensor of the present invention. Please refer to FIG. 4, which illustrates a block diagram of a low ohmic current sensor according to still another embodiment of the present invention. As illustrated in FIG. 4, the low ohmic current sensor includes an untrimmed resistor 100, an adjustable amplifier unit 110, a control unit 120, a memory unit 130, a protection unit 140, and a temperature coefficient compensation unit 150.

The functions of the untrimmed resistor 100, the adjustable amplifier unit 110, the control unit 120, the memory unit 130, and the protection unit 140 have been specified above, so they will not be readdressed here.

The temperature coefficient compensation unit 150 is coupled with the adjustable amplifier unit 110 to minimize a drift of the voltage transfer curve (V_{OUT} versus V_{CS}) caused by a temperature change. As the temperature coefficient compensation function is well known, it will not be addressed further.

With the designs elaborated above, the present invention possesses the following advantages:

1. The low ohmic current sensor of the present invention is capable of using an untrimmed resistor to provide a required resistance.

2. The low ohmic current sensor of the present invention is capable of using a programmable amplifier circuit to multiply the resistance of an untrimmed resistor with a gain to result in a required resistance.

3. The low ohmic current sensor of the present invention is capable of using a memory to store control data for resulting in a required resistance without the need of trimming a resistor.

While the invention has been described by way of example and in terms of preferred embodiments, it is to be understood that the invention is not limited thereto. To the contrary, it is intended to cover various modifications and similar arrangements and procedures—for example, the output voltage V_{OUT} can be further processed to provide a digital output, and the scope of the appended claims therefore should be accorded the broadest interpretation so as to encompass all such modifications and similar arrangements and procedures.

In summation of the above description, the present invention herein enhances the performance than the conventional structure and further complies with the patent application requirements and is submitted to the Patent and Trademark Office for review and granting of the commensurate patent rights.

What is claimed is:

1. A low ohmic current sensor capable of using untrimmed resistor to provide required resistance, comprising:
an untrimmed resistor having a first end for introducing in a current and a second end for outputting said current;
an adjustable amplifier unit, having an input port coupled with said first end and said second end to receive a current-sense voltage, an output port for providing an output voltage, and a control port for receiving at least one control signal to determine a voltage transfer curve relating said output voltage to said current-sense voltage;
a control unit, having a first port coupled with said control port to provide said at least one control signal, and a second port for accessing at least one control data, wherein said at least one control signal is generated according to said at least one control data; and
a memory unit for storing said at least one control data.

2. The low ohmic current sensor capable of using untrimmed resistor to provide required resistance as disclosed in claim 1, wherein said control unit further comprises a third port for receiving at least one external control signal to generate said at least one control data.

3. The low ohmic current sensor capable of using untrimmed resistor to provide required resistance as disclosed in claim 1, further comprising a protection unit for providing at least one protection signal according to a comparison result of said output voltage with a first alarm value and/or a comparison result of a temperature signal with a second alarm value.

4. The low ohmic current sensor capable of using untrimmed resistor to provide required resistance as disclosed in claim 1, further comprising a temperature coefficient compensation unit coupled with said adjustable amplifier unit to minimize a drift of said voltage transfer curve caused by a temperature change.

5. The low ohmic current sensor capable of using untrimmed resistor to provide required resistance as disclosed in claim 1, wherein said adjustable amplifier unit comprises an amplifier circuit, of which an input offset and a gain are adjustable by said at least one control signal.

6. The low ohmic current sensor capable of using untrimmed resistor to provide required resistance as disclosed in claim 1, wherein said low ohmic current sensor is implemented by an integrated circuit.

7. A method for programming the low ohmic current sensor of claim 1, including:
providing a known current to flow through said untrimmed resistor; and
adjusting said at least one control data until said output voltage reaches a value equal to a product of said known current and a required resistance.

8. A low ohmic current sensor capable of using untrimmed resistor to provide required resistance, comprising:
an untrimmed resistor having a first end for introducing in a current and a second end for outputting said current;
an adjustable amplifier unit, having an input port coupled with said first end and said second end to receive a current-sense voltage, an output port for providing an output voltage, and a control port for receiving at least one control signal to determine a gain such that said output voltage is generated by multiplying said current-sense voltage with said gain;
a control unit, having a first port coupled with said control port to provide said at least one control signal, a second port for accessing at least one control data, and a third port for receiving at least one external control signal, wherein said at least one control signal is generated according to said at least one control data, and said at least one external control signal is provided by an external calibration device for determining said at least one control data in a way that, with a known current flowing through said untrimmed resistor, said at least one external control signal is varied until a ratio of said output voltage to said known current is equal to a required resistance; and
a memory unit for storing said at least one control data.

9. The low ohmic current sensor capable of using untrimmed resistor to provide required resistance as disclosed in claim 8, further comprising a protection unit for providing at least one protection signal according to a comparison result of said current with an alarm current value and/or a comparison result of a temperature signal with an alarm temperature value.

10. The low ohmic current sensor capable of using untrimmed resistor to provide required resistance as disclosed in claim 8, further comprising a temperature coefficient compensation unit coupled with said adjustable amplifier unit to minimize a drift of said gain caused by a temperature change.
